(19) United States
(12) Patent Application Publication
(10) Pub. No.: US 2007/0068446 A1
(43) Pub. Date: Mar. 29, 2007

(54) Compound semiconductor single crystal and production process thereof

(76) Inventor: Fumio Matsumoto, Saitama (JP)

Correspondence Address: SUGHRUE MION, PLLC, 2100 PENNSYLVANIA AVENUE, N.W., SUITE 800, WASHINGTON, DC, 20037, US

(21) Appl. No.: 10/575,081

(22) PCT Filed: Oct. 8, 2004
(86) PCT No.: PCT/JP04/15311

§ 371 Date: Nov. 28, 2006

Related U.S. Application Data
(60) Provisional application No. 60/512,858, filed on Oct. 22, 2003.

(30) Foreign Application Priority Data
Oct. 10, 2003 (JP) 2003-351827

(51) Int. Cl. C30B 15/00; C30B 21/06; C30B 27/02; C30B 28/10; C30B 30/04

(52) U.S. Cl. 117/13

(57) ABSTRACT

A process for producing a compound semiconductor single crystal includes bringing a molten raw material liquid into contact with a seed crystal accommodated in a lower section of a crucible and gradually cooling the molten raw material liquid in the crucible so that solidification of the raw material liquid proceeds upward, thereby growing a single crystal. The seed crystal has a diameter which is 0.50 to 0.96 times that of a constant-diameter portion of the single crystal. A diameter-increasing portion of the single crystal has a diameter increased during growth of the single crystal such that a peripheral wall of the diameter-increasing portion is inclined at 5° or more and less than 35° with respect to a crystal growth direction, followed by growth of a constant-diameter portion of the single crystal.

### CROSS REFERENCE TO RELATED APPLICATIONS

This application is an application filed under 35 U.S.C. §111(a) claiming the benefit pursuant to 35 U.S.C. §119(e) (1) of the filing date of Provisional Application Ser. No. 60/512,858 filed Oct. 22, 2003 pursuant to 35 U.S.C. §111(b).

### TECHNICAL FIELD

The present invention relates to a process for producing a single crystal of a compound semiconductor, such as of GaAs or InP, by means of the vertical gradient freezing (hereinafter referred to as the “VGF”) method or the vertical Bridgman (hereinafter referred to as the “VB”) method.

### BACKGROUND ART

The liquid encapsulated Czochralski (hereinafter referred to as the “LEC”) method has generally been employed for producing a GaAs single crystal or an InP single crystal. The LEC method is advantageous in that it can relatively easily produce a wafer of large diameter. However, the LEC method involves problems in that a crystal having a high dislocation density, which would affect device characteristics or device life, is grown because of a high temperature gradient in the crystal growth direction. Meanwhile, the VGF or VB method is advantageous in that it can reduce the temperature gradient in the crystal growth direction, and thus it easily produces a crystal of low dislocation density. However, in the VGF or VB method, a crystal is grown at low temperature gradient, and thus generation of twin crystals tends to occur as a result of non-uniform crystal growth due to the temperature fluctuation in a furnace. In addition, polycrystallization tends to occur through accumulation of dislocations contained in a grown crystal which are propagated from a seed crystal or accumulation of dislocations which are formed by thermal stress generated in the grown crystal. Therefore, the VGF or VB method encounters difficulty in producing a single crystal of low dislocation density with high reproducibility.

The probability of generation of twin crystals is closely related to the inclination angle of the diameter-increasing portion of a crystal, which portion is formed between the constant-diameter portion of the crystal and a seed crystal. In the case of growth of a (100) crystal, a (111) facet plane is formed at the diameter-increasing portion of the crystal, and twin crystals are generated from the facet plane. Since the angle between the (111) facet plane and the (100) crystal plane is 54.7°, in order to prevent formation of the facet plane, the angle of the diameter-increasing section of a crucible with respect to the crystal growth direction is preferably regulated to 35.3° (i.e., 90°-54.7°) or less. However, when the angle of the diameter-increasing section is reduced, the length of the diameter-increasing portion of a crystal to be grown is increased, and crystal growth requires a long period of time, resulting in low yield of a wafer and poor productivity. In order to solve these problems, there has been reported a method for growing a crystal while maintaining the angle of the diameter-increasing portion thereof at 40 to 50° (see Handotai Kenkyu (“Semiconductor Research”), Vol. 35, edited by Junichi Nishizawa, Kogyo Chosakai Publishing Co., Ltd., page 19).

However, when a crystal is grown through this method, the angle of the diameter-increasing portion of the crystal exceeds 35°, at which twin crystals are generated. Particularly when an InP crystal is to be grown through this method, difficulty is encountered in producing a single crystal.

In the case where a compound semiconductor single crystal having a zincblende structure is to be grown by means of the VGF or VB method, when there is employed a crucible whose bottom is inclined at a predetermined angle (80° or more and less than 90°) with respect to the crystal growth direction, and the temperature gradient (in the crystal growth direction) of at least the inclined bottom of the crucible is regulated to 1° C./cm or more and less than 5° C./cm during crystal growth, the single crystal is grown without forming a diameter-increasing portion. Thus, the time required for forming a portion between the shoulder portion and the constant-diameter portion of the crystal is shortened, and facet growth is suppressed, thereby preventing generation of twin crystals (see JP-A HEI 10-87392). According to this prior art, the temperature fluctuation in the crucible (which hermetically contains a raw material and a liquid encapsulant) must be regulated so as to fall within ±0.1° C. as measured by a thermocouple provided at a position on the outer wall of the crucible, the position corresponding to the bottom of the crucible. However, particularly when an InP crystal is to be grown, the pressure in the crucible must be increased to 30 to 50 atm (3 to 5 MPa) during crystal growth, and therefore the temperature fluctuation in the crucible, which is caused by convection of a gas contained in the crucible, is very difficult to reduce. Reduction of the temperature fluctuation requires precise temperature control, and thus requires high cost.

Meanwhile, there has been reported a crystal growth technique employing a seed crystal having almost the same cross-sectional shape and dimensions as those of a crystal to be grown. According to this technique, no diameter-increasing portion is formed, and therefore precise temperature control is not required. In addition, a single crystal is grown at high yield, since formation of a diameter-increasing portion, which is generally inevitable in the case of growth of a crystal, can be prevented (see Advanced Electronics Series I-4, Baruku Kessho Seicho Gijutsu (“Bulk Crystal Growth Technique”), edited and authored by Keigo Hoshikawa, Baifukan Co., Ltd., page 239).

However, when a crystal of large diameter is to be grown through this technique, a seed crystal of large diameter not readily available at present must be employed.

In order to solve the aforementioned problems, objects of the present invention are to provide a process for producing a high-quality single crystal of a compound semiconductor, the single crystal having a large diameter (e.g., 3 inches or more), and to produce a compound semiconductor single crystal having a low average dislocation density (preferably less than 5,000 dislocations/cm²).

### DISCLOSURE OF THE INVENTION

In order to attain the aforementioned objects, the present invention provides a process for producing a single crystal of a compound semiconductor, which process comprises bringing a molten raw material liquid into contact with a seed crystal accommodated in a lower section of a crucible; and gradually cooling the molten raw material liquid in the crucible so that solidification of the raw material liquid proceeds upward, to thereby grow a single crystal, wherein the seed crystal has a diameter which is 0.50 to 0.96 times that of a constant-diameter portion of the single crystal, and a diameter-increasing portion of the single crystal has a diameter increased during growth of the single crystal such that a peripheral wall of the diameter-increasing portion is inclined at 5° or more and less than 35° with respect to a crystal growth direction, followed by growth of a constant-diameter portion of the single crystal.

In the process for producing a compound semiconductor single crystal, the seed crystal has an average dislocation density of less than 10,000 dislocations/cm².

In the first or second mentioned process for producing a compound semiconductor single crystal, the seed crystal has a diameter of at least 50 mm.

In any one of the first to third mentioned processes for producing a compound semiconductor single crystal, the constant-diameter portion has a diameter of at least 75 mm.

In any one of the first to fourth mentioned processes for producing a compound semiconductor single crystal, the diameter-increasing portion has a length of 20 to 100 mm as measured in the crystal growth direction.

In any one of the first to fifth mentioned processes for producing a compound semiconductor single crystal, the compound semiconductor is a GaAs or InP semiconductor.

The present invention also provides a single crystal of a compound semiconductor produced through any one of the first to sixth mentioned processes for producing a compound semiconductor single crystal, wherein the compound semiconductor single crystal has an average dislocation density of less than 5,000 dislocations/cm².

In the compound semiconductor single crystal, the compound semiconductor is a GaAs or InP semiconductor.

The invention also provides a crucible for growing a single crystal which is employed for a compound semiconductor single crystal growth process in which a molten raw material liquid is brought into contact with a seed crystal accommodated in a lower section of a crucible, and the molten raw material liquid is gradually cooled in the crucible so that solidification of the raw material liquid proceeds upward, to thereby grow a single crystal, the crucible comprising a seed crystal accommodation section; a diameter-increasing section which is provided atop the seed crystal accommodation section and which has an outer wall inclined at 5° or more and less than 35° with respect to a crystal growth direction; and a constant-diameter section provided atop the diameter-increasing section, wherein the seed crystal accommodation section has an inner diameter which is 0.50 to 0.96 times that of the constant-diameter section.

In the crucible for growing the single crystal, the seed crystal accommodation section has an inner diameter of at least 50 mm.

In the first or second mentioned crucible for growing a single crystal, the constant-diameter section has a diameter of at least 75 mm.

In any one of the first to third mentioned crucible for growing a single crystal, the diameter-increasing section has a length of 20 to 100 mm.

The present inventors have successfully developed a process for reliably and readily producing a compound semiconductor single crystal having a large diameter and a low dislocation density, which single crystal has conventionally been considered to be difficult to produce, by means of the VGF or VB method.

The above and other objects, characteristic features and advantages will become apparent from the description to be made herein below with reference to the accompanying drawings.

### BRIEF DESCRIPTION OF THE DRAWINGS

FIG. 1 is a schematic cross-sectional view showing a crystal growth furnace employed in the case where the VGF method is employed in the process of the present invention.

FIG. 2 is a schematic cross-sectional view showing a seed crystal and a crucible employed in the process of the present invention.

FIG. 3 is a schematic cross-sectional view showing a seed crystal and a crucible employed in Comparative Example.

### BEST MODE FOR CARRYING OUT THE INVENTION

An InP substrate having a diameter as large as 3 inches or more is increasingly envisaged to be employed in optical communication devices or electronic devices, or to be employed as a substrate on which such devices are mounted for producing an optoelectronic integrated circuit (OEIC). In order to enhance the yield of such a device, preferably, a substrate having a low dislocation density (i.e., an average dislocation density of 5,000 dislocations/cm²) is employed. In order to produce a crystal having a low dislocation density (i.e., an average dislocation density of 5,000 dislocations/cm²), preferably, a seed crystal having a low dislocation density (i.e., an average dislocation density of less than 10,000 dislocations/cm²) is employed, in considering that the amount of dislocations (propagated from the seed crystal) contained in the resultant crystal is reduced to possibly as low as one-tenth that of dislocations contained in the seed crystal. Initially, the present inventors made an attempt to employ a seed crystal having a diameter of 3 inches (i.e., a seed crystal having the same cross-sectional shape and dimensions as those of a crystal to be grown) for growing a crystal having a diameter of 3 inches by means of the VGF or VB method. However, when a 2-inch seed crystal having a low dislocation density (i.e., less than 10,000 dislocations/cm²), which is readily available, is employed, difficulty is encountered in producing, through a technique belonging to the state of the art, a single crystal having a diameter as large as 3 inches or more and sufficiently low dislocation density, since thermal stress is generated in the single crystal during crystal growth or cooling. Meanwhile, employment of a seed crystal having such a large diameter and an average dislocation density of less than 10,000 dislocations/cm², which seed crystal is not readily available, requires high production cost.

The production process of the present invention produces a single crystal whose constant-diameter portion has a diameter of 3 or 4 inches, by use of a relatively readily available crystal serving as a seed crystal (e.g., a crystal having an average dislocation density of 10,000 dislocations/cm² and a diameter of 2 inches). The resultant single crystal has an average dislocation density of 10,000 dislocations/cm² or less. When the single crystal is employed as a seed crystal, a single crystal having a larger diameter can be produced.

A characteristic feature of the production process of the present invention resides in that the process employs the VB or VGF method; a crucible including a seed crystal accommodation section at its bottom, a diameter-increasing section which is provided atop the accommodation section and is inclined at 5° or more and less than 35° with respect to the crystal growth direction, and a constant-diameter section provided atop the diameter-increasing section; and a seed crystal having a diameter which is 0.50 to 0.96 times that of a constant-diameter portion of a single crystal to be produced. When the diameter-increasing section is inclined by less than 5° with respect to the crystal growth direction, the length of that section becomes excessively large, resulting in failure to produce a single crystal whose constant-diameter portion has a target diameter. In addition, a large production apparatus and high cost are required.

In contrast, when the diameter-increasing section is inclined by 35° or more with respect to the crystal growth direction, twin crystals are generated. The angle between the diameter-increasing section and the crystal growth direction is more preferably 20 to 30°.

When the diameter of the seed crystal to be employed is less than 0.5 times or 0.96 times or more that of the constant-diameter portion of the single crystal, an additional step is required for processing of a presently available 2-inch or 3-inch seed crystal. The ratio of the seed crystal diameter to the constant-diameter portion diameter is preferably 0.6 to 0.8.

Preferably, the diameter (inner diameter) of the seed crystal accommodation section of the crucible is 50 mm or more, and the length of the constant-diameter section of the crucible is 75 mm or more. The length of the diameter-increasing section is preferably 20 to 100 mm as measured in the crystal growth direction. The seed crystal to be employed preferably has an average dislocation density of less than 10,000 dislocations/cm² and a diameter of 50 mm or more.

The above-described production process can produce a single crystal (e.g., an InP or GaAs single crystal) having an average dislocation density of less than 5,000 dislocations/cm².

Next will be described an embodiment of the production process of the present invention by taking, as an example, growth of an InP crystal.

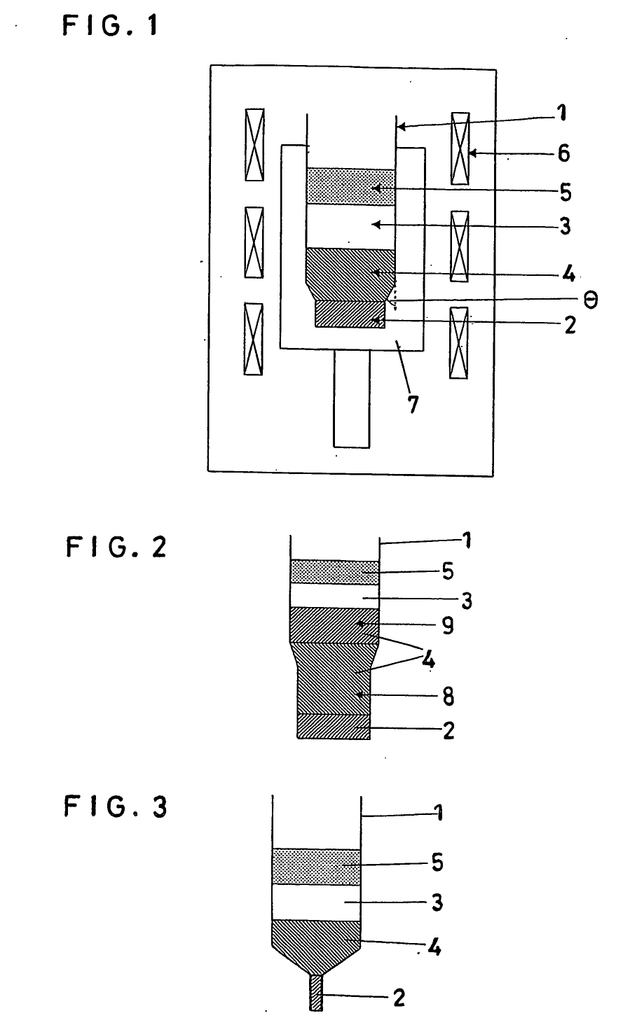

FIG. 1 is a schematic cross-sectional view showing a crystal growth furnace employed in the case where the VGF method is employed in the production process of the present invention. In FIG. 1, reference numeral 1 denotes a BN-made crucible. The crucible includes a seed crystal accommodation section having a diameter of 50 mm or more at its bottom; a diameter-increasing section which is provided atop the accommodation section and is inclined by an angle (θ) of 5° or more and less than 35° with respect to the crystal growth direction; and a constant-diameter section having a diameter equal to that of a single crystal to be grown.

The accommodation section provided at the bottom of the crucible accommodates a seed crystal 2 having a low dislocation density, i.e., an average dislocation density of less than 10,000 dislocations/cm². A molten raw material liquid 3 of InP crystal is provided atop the seed crystal 2. Reference numeral 4 denotes a crystal which has been grown upward from the seed crystal 2 through solidification of the molten raw material liquid 3. The top surface of the molten raw material liquid is covered with a liquid encapsulant 5 (B₂O₃) so as to prevent evaporation of phosphorus from the molten liquid. Reference numeral 6 denotes a heater which is provided for melting the raw material 3 and the encapsulant 5, for maintaining the temperature of the section of the crucible where the seed crystal 2 is accommodated at a low level such that a crystal can be grown on the seed crystal, and for forming a temperature profile such that the temperature increases upward in the crucible. Reference numeral 7 denotes a susceptor for supporting the crucible.

This growth furnace is provided in a high-pressure container, and the furnace is filled with an inert gas. The molten raw material liquid is solidified by controlling the temperature of the seed crystal accommodation section by the heater, to thereby grow a crystal upward from the seed crystal. In the case where the VB method is employed, the heater and the crucible are moved relative to each other, to thereby grow a crystal through solidification of the molten raw material liquid.

A crystal of low dislocation density which has been produced through a typical LEC method is not suitable for use as a seed crystal, since, when such a crystal is employed as a seed crystal, the dislocation density of a crystal grown on the seed crystal fails to be reduced sufficiently. The present invention employs, as a seed crystal, a crystal of low dislocation density which has been grown by means of, instead of the typical LEC method, a modified LEC method or horizontal boat method in a Group V element atmosphere at low temperature gradient. Needless to say, a crystal of low dislocation density which has been grown through the process of the present invention employing the VGF or VB method can be used as a seed crystal.

The average dislocation density of a crystal is obtained by calculating the average of dislocation densities as measured, at intervals of 5 mm in a radial direction, in the surface of a wafer cut out of the crystal.

The seed crystal to be employed may be a crystal which is not doped with a dopant (i.e., a non-doped crystal), or a crystal doped with an element which constitutes a crystal to be grown. The seed crystal may be recycled.

The process of the present invention is advantageous in that a crystal having two or more different diameters (e.g., a crystal having diameters of 2 inches and 3 inches) can be grown in a single crystal growth step by regulating the height of the seed crystal accommodation section of the crucible as shown in FIG. 2, and by regulating the angle between the diameter-increasing section and the crystal growth direction within a range of 5° or more and less than 35°.

The present invention will next be described by way of a specific example.

### EXAMPLE

A VGF furnace shown in FIG. 1 was employed as a crystal growth apparatus.

There was employed a BN-made crucible (total length: 250 mm) including a seed crystal accommodation section (inner diameter: 52 mm, height: 20 mm), a diameter-increasing section (angle with respect to the crystal growth direction: 30°, length as measured in the crystal growth direction: 24 mm), and a constant-diameter section (inner diameter: 80 mm). Firstly, a seed crystal (diameter: 51.5 mm, thickness: 20 mm), an InP polycrystalline raw material (2500 g), Fe serving as a dopant (0.03 wt % on the basis of the weight of the polycrystalline raw material), and B₂O₃ (400 g) were fed into the BN-made crucible, and the crucible was accommodated in a susceptor. The seed crystal employed was a crystal (average dislocation density: 8,000 dislocations/cm²) which had been grown by means of a modified LEC method (instead of a typical LEC method) in a phosphorus atmosphere. The susceptor containing the seed crystal, the polycrystalline raw material and B₂O₃ was placed in the furnace, and argon gas (i.e., an inert gas) was brought into the furnace, whereby the pressure in the furnace was regulated to 40 atm (4 MPa). The furnace was heated to about 1,070° C. by use of a heater such that B₂O₃ and the polycrystalline raw material were melted. After complete melting of the polycrystalline raw material was confirmed, the temperature of the seed crystal accommodation section was regulated to the melting point of InP (1,062° C.), and the temperature of the furnace was decreased such that the crystal growth rate became 2 mm/hr. After crystal growth was performed for about 50 hours, the furnace was cooled to room temperature over 10 hours.

After the furnace was cooled to room temperature, the crucible was removed from the furnace. B₂O₃ contained in the BN crucible was dissolved in alcohol, to thereby yield an Fe-doped InP single crystal ingot having a diameter of 3 inches and a total length of 90 mm. The singe crystal ingot thus obtained was found to contain no twin crystals. The single crystal ingot was cut into pieces, and the dislocation density thereof was measured. As a result, the single crystal was found to have a low dislocation density i.e., an average dislocation density of 2,500 dislocations/cm².

In a manner similar to that described above, Fe-doped InP single crystal growth tests were performed five times by use of a seed crystal having an average dislocation density of less than 10,000 dislocations/cm². In one of the five tests, generation of twin crystals was observed at the diameter-increasing portion of the resultant single crystal. In contrast, in four of the five tests, an InP single crystal containing no twin crystals and having a low dislocation density (i.e., less than 5,000 dislocations/cm²) was produced at high yield.

### COMPARATIVE EXAMPLE

The procedure of the aforementioned Example was repeated, except that there were employed a BN-made crucible (total length: 250 mm) including a seed crystal accommodation section (inner diameter: 10 mm, height: 40 mm), a diameter-increasing section (angle with respect to the crystal growth direction: 45°) and a constant-diameter section (inner diameter: 80 mm), and a seed crystal having a diameter of 9.5 mm and a length of 40 mm, to thereby grow an InP crystal. Generation of twin crystals was observed at an initially grown portion of the diameter-increasing portion of the resultant Fe-doped crystal. In a manner similar to that described above, InP crystal growth tests were performed five times. In all the tests, generation of twin crystals was observed at the diameter-increasing portion of the resultant crystal, and a single crystal failed to be obtained.

### INDUSTRIAL APPLICABILITY

The process of the present invention can produce, at high yield, a single crystal of a compound semiconductor (e.g., of GaAs or InP) having high quality, low dislocation density and large diameter, which single crystal is employed in high-speed, high-frequency electronic devices in the field of, for example, optical communication or radio communication. The compound semiconductor single crystal of large diameter can be employed in optical communication devices or electronic devices, and employed as a substrate for optoelectronic integrated circuits.

1. A process for producing a single crystal of a compound semiconductor, comprising bringing a molten raw material liquid into contact with a seed crystal accommodated in a lower section of a crucible and gradually cooling the molten raw material liquid in the crucible so that solidification of the raw material liquid proceeds upward, thereby growing a single crystal, wherein the seed crystal has a diameter which is 0.50 to 0.96 times that of a constant-diameter portion of the single crystal, and a diameter-increasing portion of the single crystal has a diameter increased during growth of the single crystal such that a peripheral wall of the diameter-increasing portion is inclined at 5° or more and less than 35° with respect to a crystal growth direction, followed by growth of a constant-diameter portion of the single crystal.

2. The process for producing a compound semiconductor single crystal according to claim 1, wherein the seed crystal has an average dislocation density of less than 10,000 dislocations/cm².

3. The process for producing a compound semiconductor single crystal according to claim 1, wherein the seed crystal has a diameter of at least 50 mm.

4. The process for producing a compound semiconductor single crystal according to claim 1, wherein the constant-diameter portion has a diameter of at least 75 mm.

5. The process for producing a compound semiconductor single crystal according to claim 1, wherein the diameter-increasing portion has a length of 20 to 100 mm as measured in the crystal growth direction.

6. The processes for producing a compound semiconductor single crystal according to claim 1, wherein the compound semiconductor is a GaAs or InP semiconductor.

7. A single crystal of a compound semiconductor produced through the process for producing a compound semiconductor single crystal as recited in claim 1, wherein the compound semiconductor single crystal has an average dislocation density of less than 5,000 dislocations/cm².

8. The compound semiconductor single crystal according to claim 7, wherein the compound semiconductor is a GaAs or InP semiconductor.

9. A crucible for growing a single crystal which is employed for a compound semiconductor single crystal growth process in which a molten raw material liquid is brought into contact with a seed crystal accommodated in a lower section of a crucible, and the molten raw material liquid is gradually cooled in the crucible so that solidification of the raw material liquid proceeds upward, to thereby grow a single crystal, the crucible comprising a seed crystal accommodation section; a diameter-increasing section which is provided atop the seed crystal accommodation section and which has an outer wall inclined at 5° or more and less than 35° with respect to a crystal growth direction; and a constant-diameter section provided atop the diameter-increasing section, wherein the seed crystal accommodation section has an inner diameter which is 0.50 to 0.96 times that of the constant-diameter section.

10. The crucible for growing the single crystal according to claim 9, wherein the seed crystal accommodation section has an inner diameter of at least 50 mm.

11. The crucible for growing a single crystal according to claim 9, wherein the constant-diameter section has a diameter of at least 75 mm.

12. The crucible for growing a single crystal according to claim 9, wherein the diameter-increasing section has a length of 20 to 100 mm.
